(19) United States
(12) Patent Application Publication
(10) Pub. No.: US 2026/0324167 A1
(43) Pub. Date: Oct. 15, 2026

(54) A LIGHT EMITTING FILAMENT-SHAPED DEVICE

(71) Applicant: SIGNIFY HOLDING B.V., EINDHOVEN (NL)

(72) Inventors: ALDEGONDA LUCIA WEIJERS, EINDHOVEN (NL); MARTINUS PETRUS JOSEPH PEETERS, WEERT (NL); JAN DE GRAAF, UDEN (NL)

(21) Appl. No.: 19/117,120

(22) PCT Filed: Oct. 3, 2023
(86) PCT No.: PCT/EP2023/077305

§ 371 Date: Mar. 31, 2025

(30) Foreign Application Priority Data
Oct. 7, 2022 (EP) 22200220.6

(51) Int. Cl. H10H 29/851; F21K 9/232

(52) U.S. Cl. CPC H10H 29/8512; F21K 9/232

(57) ABSTRACT

A light emitting device, LED, filament (1) configured to, in operation, emit LED filament light, the LED filament (1) comprising a phosphor structure (3), a plurality of first LEDs (4) adapted for, in operation, emitting first LED light, and being arranged A1 underneath the phosphor structure (3), a plurality of second LEDs (5) adapted for, in operation, emitting second LED light, the second LED light being red light, a plurality of third LEDs (6) adapted for, in operation, emitting third LED light, the third LED light being green light, and a plurality of fourth LEDs (7) adapted for, in operation, emitting fourth LED light, the fourth LED light being blue light, an electrical circuitry (11) coupled to the pluralities of LEDs (4, 5, 6, 7), and an elongated carrier (8), the pluralities of LEDs (4, 5, 6, 7) being arranged on a first major surface (81) of the elongated carrier (8), wherein the phosphor structure (3) comprises a phosphor adapted for generating cold white (CW) light and a phosphor adapted for generating warm white (WW) light, and wherein the first LED light comprises or is light with a wavelength of 405 nm and the phosphor structure (3) is configured to be excited using only light having a wavelength of 405 nm.

### FIELD OF THE INVENTION

The invention relates to a light emitting device, LED, filament configured to, in operation, emit LED filament light, the LED filament comprising a phosphor structure, a plurality of first LEDs adapted for, in operation, emitting first LED light, and being arranged underneath the phosphor structure, a plurality of second LEDs adapted for, in operation, emitting second LED light, and being arranged underneath the phosphor structure, the second LED light being red light, a plurality of third LEDs adapted for, in operation, emitting third LED light, and being arranged underneath the phosphor structure, the third LED light being green light, a plurality of fourth LEDs adapted for, in operation, emitting fourth LED light, and being arranged underneath the phosphor structure, the fourth LED light being blue light, an electrical circuitry coupled to the plurality of first, second, third and fourth LEDs, and an elongated carrier.

WO2022/207603A1 discloses a LED filament lamp with a filament having a first LED filament side, a second LED filament side, an intermediate layer, and a plurality of light sources. The plurality of light sources comprises first sources of light to generate first white light having a first correlated color temperature CCT1 and being associated to the first filament side, and second sources of light to generate second white light having a second correlated color temperature and being associated to the first filament side, and wherein CCT2−CCT1≥500 K. The plurality of light sources further comprises third sources of light to generate blue third light and being associated to the second filament side, fourth sources of light to generate green fourth light and being associated to the second filament side, and fifth sources of light to generate red fifth light and being associated to the second filament side. The intermediate layer is configured between at least part of the first LED filament side and at least part of the second LED filament side.

US2020/3553331A discloses a light-emitting system with LEDs emitting a first radiation characterized by a first wavelength in the range of 390-430 nm, a first wavelength conversion material for converting a part of the first radiation to a second radiation characterized by a second wavelength in a second range from about 500 nm to about 600 nm, and a second wavelength conversion for converting a part of the first radiation to a third radiation characterized by a third wavelength in a third range from about 600 to about 700 nm. The light spectrum has an R9 of at least 80 and is characterized by a spectral power distribution in which a violet fraction is at least 0.10.

As used herein, the terms light emitting device and LED are intended to encompass both LED packages, LED dies and bare LEDs.

As used herein, warm white (WW) light is intended to refer to light having a color temperature being in the range of 2000 K to 3300 K.

As used herein, cold white (CW) light is intended to refer to light having a color temperature being in the range of 3300 K to 5300 K.

As used herein, white light similar to daylight is intended to refer to light having a color temperature being in the range of 5300 K to 7000 K or 5300 K to 6500 K.

### BACKGROUND OF THE INVENTION

A current trend in lighting is the use of LED filament lamps. A LED filament lamp is a LED lamp which comprises a LED filament, and which is designed to resemble a traditional incandescent light bulb with a visible filament for aesthetic and light distribution purposes, but with the high efficiency of light-emitting diodes.

A LED filament is providing LED filament light and comprises a plurality of light emitting diodes (LEDs) arranged in a linear array. Preferably, the LED filament has a length L and a width W, wherein L>5 W. The LED filament may be arranged in a straight configuration or in a non-straight configuration such as for example a curved configuration, a 2D/3D spiral or a helix. Preferably, the LEDs are arranged on an elongated carrier like for instance a carrier, that may be rigid (made from, e.g., a polymer, glass, quartz, metal or sapphire) or flexible (e.g., made of a polymer or metal, e.g., a film or foil).

In case the carrier comprises a first major surface and an opposite second major surface, the LEDs are arranged on at least one of these surfaces. The carrier may be reflective or light transmissive, such as translucent and preferably transparent.

The LED filament may comprise an encapsulant at least partly covering at least part of the plurality of LEDs. The encapsulant may also at least partly cover at least one of the first major surface and second major surface. The encapsulant may be a polymer material which may be flexible such as for example a silicone. Further, the LEDs may be arranged for emitting LED light e.g. of different colors or spectrums. The encapsulant may comprise a luminescent material that is configured to at least partly convert LED light into converted light. The luminescent material may be a phosphor such as an inorganic phosphor and/or quantum dots or rods.

The LED filament may comprise multiple sub-filaments.

Known tunable white filament lamps consist of at least two filaments, one with low correlated color temperature (CCT) and one with High CCT. Sometimes a single filament is used that combines this low CCT and high CCT emission.

WO2021/018646 A1 discloses a LED filament including a linear array of LEDs arranged on a carrier substrate, wherein the linear array is divided into two separate longitudinal sections, a first longitudinal section including only LEDs configured to emit white light, and a second longitudinal section including only LEDs configured to emit color controllable light. It is suggested to confine the color LEDs to the second longitudinal section of the array, so that the first longitudinal section of the array is capable of emitting homogenous white light of a color temperature in the range of the LEDs in that section.

When it is desired to add colors to make a full color light emitting diode (LED) filament lamp, the color LEDs can be added into the lamp as a separate filament. This is usually not preferred due to resulting in an unpleasant appearance. Alternatively, the color LEDs can be placed on the same surface of filament substrate, that is together with the white LEDs. However, if RGB and white LEDs filament strings are formed on the same printed circuit board (PCB) or flexible printed circuit (FPC) surface of the filament, there can be unwanted cross-talk of light between the RGB LED filament strings and the white LED filament strings, next to cross talk between cool-white (CW) and warm-white (WW) LED filament strings. Such cross-talk will significantly reduce the color-gamut produced by this filament in a clear bulb. For instance, when light is emitted by the direct blue LED it will be absorbed by the red-yellow phosphor layer provided on top of the white LED filament string and will cause unwanted conversion and thus unwanted red-yellow light generation. This unwanted red-yellow light emission will cause a shift of the filament color point from pure blue towards less saturated color points. Such un-saturated color appearance is not preferred for color tunable lamps, especially for high-demanding color tunable lamps with white-color ambiance.

Furthermore, saturated colors (especially blue) cannot be made using a filament lamp, in which the direct emitters (LEDs) are covered using a phosphor or a phosphor mixture. The blue light will excite some yellow/green-red phosphors, leading to a very unsaturated blue color. However, phosphors are needed to generate the cool white and warm white light with a high light quality.

An issue with the high quality white light on the black body locus (BBL) and with a high color rendering index (CRI) is that next to the CW (color temperature of 4500 K or higher or 3300 K or higher) and WW light (color temperature of around 2200 K or between 2000 K and 3300 K) which are on the BBL, a green contribution is needed to make intermediate Correlated Color Temperature (CCT) white light (that is of a color temperature between 2200 K and 4500 K) on the BBL. This is detrimental to the look and feel of the filament which shows without any measures the green emitting LEDs next to the emitting white channels when looking at the filament giving it a cheap low-quality image.

It is therefore desired to provide a WW-CW filament lamp that, in operation, produces high quality white light in the black body locus (BBL) as well as a high color rendering index (CRI).

It is further, and more particularly, desired to provide a 5 channel (RGB WW-CW) filament lamp that, in operation, produces saturated colors (Red, Green and Blue) and high quality white light in the BBL as well as a high CRI.

### SUMMARY OF THE INVENTION

It is thus an object of the present invention to overcome the above-mentioned problems, and to provide a WW-CW filament lamp that, in operation, produces high quality white light in the black body locus (BBL) as well as a high color rendering index (CRI).

It is further, and more particularly, desired to provide a 5 channel (RGB WW-CW) filament lamp that, in operation, produces saturated colors (Red, Green and Blue) and high quality white light in the BBL as well as a high CRI.

It is also desired to provide such a filament lamp with improved color homogeneity when multiple colors are emitted, and thus with and high color gamut and improved aesthetics of the filament.

According to a first aspect of the invention, this and other objects are achieved by a light emitting device, LED, filament configured to, in operation, emit LED filament light, the LED filament comprising a phosphor structure, a plurality of first LEDs adapted for, in operation, emitting first LED light, the plurality of first LEDs and the phosphor structure being arranged in such a way with respect to each other that the phosphor structure, in operation, is receiving the first light, a plurality of second LEDs adapted for, in operation, emitting second LED light, the second LED light being red light, the plurality of second LEDs and the phosphor structure being arranged in such a way with respect to each other that the phosphor structure, in operation, is receiving the second light, a plurality of third LEDs adapted for, in operation, emitting third LED light, the third LED light being green light, the plurality of third LEDs and the phosphor structure being arranged in such a way with respect to each other that the phosphor structure, in operation, is receiving the third light, a plurality of fourth LEDs adapted for, in operation, emitting fourth LED light, the fourth LED light being blue light, the plurality of fourth LEDs and the phosphor structure being arranged in such a way with respect to each other that the phosphor structure, in operation, is receiving the fourth light, an electrical circuitry coupled to the first, second, third and fourth plurality of LEDs, and an elongated carrier, the plurality of first, second, third and fourth LEDs being arranged on a first major surface of the elongated carrier, where the phosphor structure comprises at least one of a phosphor adapted for generating cold white (CW) LED filament light and a phosphor adapted for generating warm white (WW) LED filament light in combination with one or more of the second LED light, the third LED light and the fourth LED light, where the phosphor structure is configured to convert less than 10 % of the second light, third light and fourth light, and where the first LED light comprises or is light with a peak wavelength in the range of 380-440 nm or 380-420 nm or 380-410 nm or 400-410 nm or of 405 nm, and the phosphor structure is configured to be excited by light having a wavelength corresponding to that of the first light. In embodiments, the phosphor structure is configured to convert less than 7%, preferably less than 5%, more preferably less than 2% of the second LED light, third LED light and fourth LED light.

Such a phosphor structure serves to generate the cool white and warm white light with a high light quality. Since the phosphor structure is not or only to a relatively low extent, excited by blue light (~450 nm), the direct blue channel, that is the fourth light emitted by the plurality of fourth LEDs, will be transmitted through the phosphor layer and not be converted. Thus, when the first plurality of LEDs are in operation and emit first light, the phosphor structure is excited and together they will emit white light. If one (or more) of the second, third and fourth LEDs (Red, Green and Blue LEDs) dies are in operation and emit LED light, the red, green and/or blue LED light will be transmitted by the phosphor structure without generating (undesired) emission. Thus, with a LED filament according to the invention and as described above, it becomes possible to provide LED filament light with a good quality white light and also saturated colors. In addition, the phosphor will scatter the red, green and/or blue LED light, and this will enhance the color homogeneity of the LED filament light and improve or increase the color gamut of the LED filament light. The wording “phosphor” may both refer to a single phosphor material or to a combination of two or more phosphor materials.

It is noted that put in other terms than the peak wavelengths of the first LED light mentioned above, it is in an embodiment ensured that the difference between the peak wavelength of the fourth LED light, or blue light, and the peak wavelength of the first LED light is larger than 40 nm, larger than 45 nm, or larger 50 nm. Given the fact that the peak wavelength of the fourth LED light will in practice most often be about 460 nm, the maximum peak wavelength for the first LED light should therefore be smaller than 410 nm. In an embodiment, the first LEDs are adapted for, in operation, emitting first LED light having a peak wavelength of or at 405 nm.

Thereby, and especially if combining with green LEDs under the phosphor structure, the percentage of conversion of the green light, such as the plurality of third LEDs described above, by the phosphor structure can be more relaxed, and in particular it does not anymore need to be smaller than 5%, since a saturated green color is not needed to be able to follow the BBL. Therefore, it is hereby enabled to provide a WW-CW filament lamp that, in operation, produces high quality white light in the black body locus (BBL) as well as a high color rendering index (CRI).

In an embodiment, the first LEDs are adapted for, in operation, emitting first LED light having a peak wavelength within ±2 nm, ±5 nm, ±10 nm or ±20 nm of 405 nm.

Using first light having a peak wavelength within +2 nm, ±5 nm, ±10 nm or ±20 nm of 405 nm, or better yet at or on 405 nm, provides the advantage that in case some first light is leaking through the phosphor layer (which light would be hardly visible), it may excite some optical whiteners, e.g., whiteners in fabrics or paper, which leads to better white perception (Crisp White).

In an embodiment, the plurality of first, second, third and fourth LEDs are arranged in sequences of a first LED followed by a group comprising a second LED, a third LED and a fourth LED.

Such a group comprising a second LED, a third LED and a fourth LED is also known as a Red-Green-Blue-group or RGB-group. The order of the three LEDs in a RGB group may for instance be RGB or BRG or any other suitable order.

Thus, a WW-CW LED filament that, in operation, produces high quality white light in the black body locus (BBL) as well as a high color rendering index (CRI) is hereby obtained. Such a LED filament furthermore has an improved color homogeneity when multiple colors are emitted and will thus also have improved aesthetics of the LED filament.

In an embodiment the LED filament comprises one single filament string.

Thereby, a four channel LED filament with a particularly simple structure is provided for.

In an embodiment the LED filament comprises a first filament string and a second filament string, and the phosphor structure is arranged on the first filament string and on the second filament string in such a way that one of the first filament string and the second filament string comprises the phosphor adapted for generating cold white (CW) light in combination with one or more of the second LED light, the third LED light and the fourth LED light, and that the other of the first filament string and the second filament string comprises the phosphor adapted for generating warm white (WW) light in combination with one or more of the second LED light, the third LED light and the fourth LED light.

Thereby, a 5 channel (RGB WW-CW) LED filament is provided for which, in operation, produces saturated colors (Red, Green and Blue) and high quality white light in the black body locus (BBL) as well as a high color rendering index (CRI).

In an embodiment the Phosphor adapted for generating WW light comprises a red phosphor arranged underneath a Phosphor adapted for generating CW light of the same type as the Phosphor adapted for generating CW light comprised by the one of the first filament string and the second filament string which comprises the Phosphor adapted for generating CW light.

This enables the use of the same production method as used in Chip-On-Board (COB) technology for manufacturing a LED filament according to the invention. Thereby, the LED filament becomes particularly simple to manufacture.

In an embodiment each of the first filament string and the second filament string comprises a plurality of first LEDs adapted for, in operation, emitting first light, and the plurality of first LEDs and the phosphor structure being arranged in such a way with respect to each other that the phosphor structure, in operation, is receiving the first light.

Thereby, high quality white light in the BBL and with an increased intensity is provided.

In an embodiment each of the first filament string and the second filament string comprises a plurality of second LEDs adapted for, in operation, emitting second LED light, the second LED light being red light, the plurality of second LEDs and the phosphor structure being arranged in such a way with respect to each other that the phosphor structure, in operation, is receiving the second light, a plurality of third LEDs adapted for, in operation, emitting third LED light, the third LED light being green light, the plurality of third LEDs and the phosphor structure being arranged in such a way with respect to each other that the phosphor structure, in operation, is receiving the third light, and a plurality of fourth LEDs adapted for, in operation, emitting fourth LED light, the fourth LED light being blue light, the plurality of fourth LEDs and the phosphor structure being arranged in such a way with respect to each other that the phosphor structure, in operation, is receiving the fourth light.

This provides for a LED filament structure where the first and second filament string are essentially identical and thus for a simplified production process.

In an embodiment, the first filament string and the second filament string, or the respective first, second, third and fourth LEDs on the first filament string and the second filament string, respectively, are arranged in such a way with respect to each other that identical LEDs, for instance respective first LEDs, of each filament string are arranged offset with respect to each other in the longitudinal direction of the LED filament.

Thereby, a filament lamp with an even further improved color homogeneity and color gamut when multiple colors are emitted, and thus with improved aesthetics of the filament, is provided for.

In an embodiment the LED filament comprises at least a first filament string and a second filament string, where the plurality of first LEDs adapted for, in operation, emitting first LED light and the phosphor structure is arranged on the first filament string, and where the plurality of second LEDs adapted for, in operation, emitting second LED light, the plurality of third LEDs adapted for, in operation, emitting third LED light, and the plurality of fourth LEDs adapted for, in operation, emitting fourth LED light is arranged on the second filament string.

Thereby, a five channel LED filament with a particularly simple structure is provided for.

In an embodiment the LED filament comprises one or more further filament strings, and where a further plurality of second LEDs adapted for, in operation, emitting second LED light is arranged on at least one of the one or more further filament strings, a further plurality of third LEDs adapted for, in operation, emitting third LED light is arranged at least one of the one or more further filament strings, and a further plurality of fourth LEDs adapted for, in operation, emitting fourth LED light is arranged on at least one of the one or more further filament strings.

Thereby, Colored (RGB) light with a high saturation and with an increased intensity is provided.

In an embodiment the phosphor structure is of a type which, when exposed to light, emits in the yellow-red wavelength region and is not excited by light in the green-blue wavelength region.

In an embodiment the phosphor structure is of a type which, when exposed to light, emits in one or more of the yellow and red wavelength region and is not excited by light in one or more of the green and blue wavelength region.

In an embodiment the phosphor structure is of a type which is not excited by light in the blue wavelength region.

In an embodiment the phosphor structure is of a type which is not excited by light with a wavelength in the region of 550 nm to 610 nm.

By either of these embodiments, it becomes possible to provide high quality white light over a wide CCT-range.

In an embodiment the phosphor structure comprises at least one phosphor chosen from the group comprising: violet pumped blue (VB) phosphors, such as (Sr, Ca, Ba)5(PO4)3Cl:Eu2+, violet pumped green (VG) phosphors, such as (Ba, Sr)MgAl10O17:Mn2+, Eu2+, and violet pumped red phosphors, such as Mg8Ge2O11F2:Mn 4+. In specific embodiments the phosphor comprises a phosphor of the type A3B5O12:Ce, wherein A in embodiments comprises one or more of Y, La, Gd, Tb and Lu, especially (at least) one or more of Y, Gd, Tb and Lu, and wherein B in embodiments comprises one or more of Al, Ga, In and Sc. Especially, A may comprise one or more of Y, Gd and Lu, such as especially one or more of Y and Lu. Especially, B may comprise one or more of Al and Ga, more especially at least Al, such as essentially entirely Al. Hence, especially suitable phosphors are cerium comprising garnet materials.

These are all particularly suitable yellow/green/red phosphors exhibiting a low (royal) blue absorption.

In an embodiment the phosphor structure comprises at least one phosphor chosen from the group comprising quantum dots materials with violet absorption and emission in green, yellow or orange/red.

These are all particularly suitable yellow/green/red quantum dot type phosphors exhibiting a low (royal) blue absorption.

In an embodiment the LED filament further comprises an encapsulant at least partially enclosing the plurality of LEDs and, where provided, the elongated carrier.

Thereby, a particularly robust and durable LED filament is provided for.

In an embodiment, at least one of the Phosphor adapted for generating CW light and the Phosphor adapted for generating WW light forms part of the encapsulant.

Thereby a LED filament with a particularly simple and compact structure is provided for.

In an embodiment, the encapsulant further comprises a translucent material.

The invention also relates to a luminaire or a lamp comprising a light emitting device according to the present invention.

The terms “blue light” or “blue emission” especially relates to light having a wavelength in the range of about 440-495 nm (including some violet and cyan hues). The terms “green light” or “green emission” especially relate to light having a wavelength in the range of about 495-570 nm. The terms “yellow light” or “yellow emission” especially relate to light having a wavelength in the range of about 570-590 nm. The terms “orange light” or “orange emission” especially relate to light having a wavelength in the range of about 590-620 nm. The terms “red light” or “red emission” especially relate to light having a wavelength in the range of about 620-780 nm. The term “pink light” or “pink emission” refers to light having a blue and a red component. The term “cyan” may refer to one or more wavelengths selected from the range of about 490-520 nm. The term “amber” may refer to one or more wavelengths selected from the range of about 585-605 nm, such as about 590-600 nm. The phrase “light having one or more wavelengths in a wavelength range” and similar phrases may especially indicate that the indicated light (or radiation) has a spectral power distribution with at least intensity or intensities at these one or more wavelengths in the indicate wavelength range. For instance, a blue emitting solid state light source will have a spectral power distribution with intensities at one or more wavelengths in the 440-495 nm wavelength range.

It is noted that the invention relates to all possible combinations of features recited in the claims.

### BRIEF DESCRIPTION OF THE DRAWINGS

This and other aspects of the present invention will now be described in more detail, with reference to the appended drawings showing embodiment(s) of the invention.

FIG. 1 shows a top view of a first embodiment of a light emitting device according to the invention.

FIG. 2 shows a top view of a second embodiment of a light emitting device according to the invention.

FIG. 3 shows a cross-sectional side view of a light emitting device according to FIG. 2.

FIG. 4 shows a top view of a third embodiment of a light emitting device according to the invention.

FIG. 5 shows a graph illustrating emission and excitation spectra of some yellow/green/red phosphors with low (royal) blue absorption by normalized intensity as a function of wavelength.

FIG. 6 shows a graph illustrating emission and excitation spectra of some yellow/green/red quantum dot (QD) type phosphors with low (royal) blue absorption by normalized intensity as a function of wavelength.

FIG. 7 shows a schematical cross-sectional side view of a lamp comprising a light emitting device according to the invention.

As illustrated in the figures, the sizes of layers and regions are exaggerated for illustrative purposes and, thus, are provided to illustrate the general structures of embodiments of the present invention. Like reference numerals refer to like elements throughout.

### DETAILED DESCRIPTION

The present invention will now be described more fully hereinafter with reference to the accompanying drawings, in which currently preferred embodiments of the invention are shown. This invention may, however, be embodied in many different forms and should not be construed as limited to the embodiments set forth herein; rather, these embodiments are provided for thoroughness and completeness, and fully convey the scope of the invention to the skilled person.

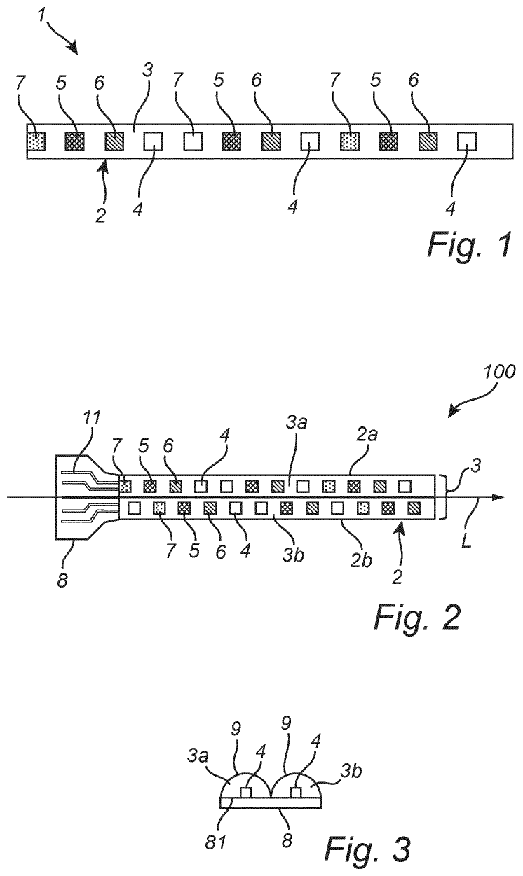

FIG. 1 shows a top view of an embodiment of a light emitting device, LED, filament 1 according to the invention. Generally, and irrespective of the embodiment, the LED filament 1 comprises a filament string 2, which comprises a phosphor structure 3 and a plurality of first LEDs 4.

It is noted that the concept of the invention as described herein, to reduce crosstalk of blue light and the phosphor by using a phosphor that is not exited by the blue light, is not limited to be applicable to light emitting devices having a filament shape but may also be applied to light emitting devices having for instance a Chip On Board (COB), a LED strip or another suitable shape.

The first LEDs 4 are adapted for, in operation, emitting first LED light. The first LED light comprises or is light with a wavelength of 405 nm. The first LEDs 4 may be adapted for, in operation, emitting first LED light having a peak wavelength of or at 405 nm. The first LEDs 4 may be adapted for, in operation, emitting first LED light having a peak wavelength within, for example, ±2 nm, ±5 nm, ±10 nm or ±20 nm of 405 nm. The first LEDs 4 and the phosphor structure 3 are arranged in such a way with respect to each other that the phosphor structure 3, in operation, is receiving the first LED light. The phosphor structure 3 is arranged in a light receiving relationship with the first LEDs 4. The first LEDs 4 are arranged underneath the phosphor structure 3. The phosphor structure 3 may cover the first LEDs 4 at least partially.

The LED filament 1 may further comprise a plurality of second LEDs 5. The second LEDs 5 are adapted for, in operation, emitting second LED light, the second LED light being red light. The second LEDs 5 are red (R) LEDs. The second LEDs 5 and the phosphor structure 3 are arranged in such a way with respect to each other that the phosphor structure 3, in operation, is receiving the second LED light. The phosphor structure 3 is arranged in a light receiving relationship with the second LEDs 5. The second LEDs 5 are arranged underneath the phosphor structure 3. The phosphor structure 3 may cover the second LEDs 5 at least partially.

The LED filament 1 may further comprise a plurality of third LEDs 6 adapted for, in operation, emitting third LED light, the third LED light being green light. The third LEDs 6 are green (G) LEDs. The third LEDs 6 and the phosphor structure 3 are arranged in such a way with respect to each other that the phosphor structure 3, in operation, is receiving the third LED light. The phosphor structure 3 is arranged in a light receiving relationship with the third LEDs 6. The third LEDs 6 are arranged underneath the phosphor structure 3. The phosphor structure 3 may cover the third LEDs 6 at least partially.

The LED filament 1 may further comprise a plurality of fourth LEDs 7 adapted for, in operation, emitting fourth LED light, the fourth LED light being blue light. The fourth LEDs 7 are blue (B) LEDs. The fourth LEDs 7 and the phosphor structure 3 are arranged in such a way with respect to each other that the phosphor structure 3, in operation, is receiving the fourth LED light. The phosphor structure 3 is arranged in a light receiving relationship with the fourth LEDs 7. The fourth LEDs 7 are arranged underneath the phosphor structure 3. The phosphor structure 3 may cover the fourth LEDs 7 at least partially.

Thus, in a more generalized sense, the first LEDs 4 may be described as being adapted for, in operation, emitting first LED light being violet light or UV light.

In the embodiment shown, there is provided three first LEDs 4, three second LEDs 5, three third LEDs 6 and three fourth LEDs 7. The number of LEDs 4, 5, 6, and 7 may be adapted to fit the length of the LED filament 1.

In the embodiment shown, the LED filament 1 comprises one filament string 2. Thus, all LEDs 4, 5, 6, and 7 are arranged on one and the same filament string 2 of the LED filament 1.

The LEDs 4, 5, 6, and 7 of the LED filament 1 may be arranged in sequences of a first LED 4, a second LED 5, a third LED 6 and a fourth LED 7 in that order. Alternatively, the LEDs 4, 5, 6, and 7 of the LED filament 1 may be arranged in sequences of a first LED 4, a fourth LED 7, a second LED 5, and a third LED 6 in that order. More generally, the LEDs 4, 5, 6, and 7 of the LED filament 1 may be arranged in sequences of a first LED 4 followed by a group comprising a second LED 5, a third LED 6 and a fourth LED 7, i.e. a RGB-group, where the three LEDs of the RGB-group may be arranged in any suitable order, such as for example RGB or BRG.

The LEDs 4, 5, 6, and 7 of the LED filament 1 are arranged on a surface 81 of a carrier 8. The carrier is not visible in FIG. 1 but is best seen in FIG. 3. The surface 81 is a first major surface 81 of the carrier 8. The carrier 8 is an elongated carrier 8. The elongated carrier 8 may be a substrate. The elongated carrier 8 or substrate may be a printed circuit board (PCB).

Electrical circuitry 11 is coupled to the LEDs 4, 5, 6, and 7 such as to supply the LEDs 4, 5, 6, and 7 with electrical energy. The electrical circuitry 11 is not visible in FIG. 1 but is shown in FIG. 2. The electrical circuitry 11 may be arranged on or in the elongated carrier 8. The electrical circuitry 11 may comprise one or more electrical tracks, such as for instance one track for each of the first, second, third and fourth LEDs respectively.

The phosphor structure 3 may be or form part of an encapsulant 9 which is best seen in FIG. 3. The encapsulant 9 at least partially encloses the LEDs 4, 5, 6, and 7 and the elongated carrier 8. The encapsulant 9 may further optionally comprise a translucent material. The translucent material of the encapsulant 9 may be a polymer, such as a silicone which is capable of withstanding high intensity light and heat. The phosphor structure 3 may be encapsulated by the encapsulant 9, such as being arranged underneath the encapsulant 9 or arranged in or forming part of the encapsulant 9. Alternatively, the phosphor structure 3 may be arranged or disposed on top of, such as on the outer surface of, the encapsulant 9.

The LED filament 1 shown in FIG. 1 is one example on how a RGB+white filament may be made according to the invention. In operation, the first LEDs 4 plus the phosphor structure 3 is used to provide LED filament light of a white color. The second, third and fourth LEDs 5, 6, 7 may be used to generate LED filament light with a different correlated color temperature (CCT) such as the CCT given by the second, blue, LEDs 5 and the phosphor structure 3, and/or to generate colored light with a very large color gamut.

In operation, when the first LEDs 4 are on, the phosphor structure 3 is excited, and the first LEDs 4 and the phosphor structure 3 will together emit white LED filament light. If one (or more) of the second, third and fourth LEDs 5, 6, and 7 are in operation, second, third and fourth LED light will be transmitted by the phosphor structure 3 without generating (undesired) emission. In this way, a LED filament is provided with which one may obtain good quality white light and also saturated colors. In addition, the phosphor structure 3 will scatter the second, third and fourth LED light, and this will enhance the color homogeneity of the LED filament light. The LED filament 1 shown in FIG. 1 is a 4 channel filament.

The phosphor structure 3 generally and irrespective of the embodiment comprises one or both of a phosphor adapted for generating cold white (CW) light adapted for generating cold white (CW) light and a phosphor adapted for generating warm white (WW) light adapted for generating warm white (WW) light, and the phosphor structure 3 is configured to be excited using only light having a wavelength corresponding to the wavelength or wavelength range of the first LED light, for instance of 405 nm. The phosphor structure 3 may additionally and optionally also comprise a phosphor adapted for generating white light similar to daylight. Generally, it is acceptable that the phosphor structure 3 is adapted to or capable of converting less than, e.g., 5% of the light from the second, third and fourth LEDs 5, 6, 7. By way of example, in case 5% of the blue light (that is the fourth LED light) is absorbed and converted by the phosphor structure, the color purity decreases by about 3% to about 95%, and for 10% absorption and conversion the color purity decreases to about 92%. More specifically, a maximum of 10% conversion, preferably a maximum of 5% conversion, and even more preferably a maximum of 2% conversion is acceptable.

The phosphor structure 3 may of a type which when exposed to light emits in the yellow-red wavelength region and is not or hardly not excited by light in the green-blue wavelength region. The phosphor structure 3 may be of a type which is not or hardly not excited by light in the blue wavelength region. The phosphor structure may be of a type which is not or hardly not excited by light in the wavelength region of 550 nm to 610 nm.

Suitable phosphors for the phosphor structure 3 include, but are not necessarily limited to, those listed below. The phosphor structure 3 may comprise one or more of such phosphors. The phosphors listed below are non-limiting examples of phosphors that emit in the yellow-red region and are not (or hardly) excited using (royal) blue light.

Suitable phosphors include for instance quantum dots materials with violet absorption and emission in green, yellow or orange/red. Suitable phosphors include for instance violet pumped blue (VB) phosphors such as (Sr, Ca, Ba)5(PO4)3Cl:Eu2+, and violet pumped green (VG) phosphors such as (Ba, Sr)MgAl10O17:Mn2+, Eu2+, and violet pumped red phosphors such as Mg8Ge2O11F2:Mn4+.

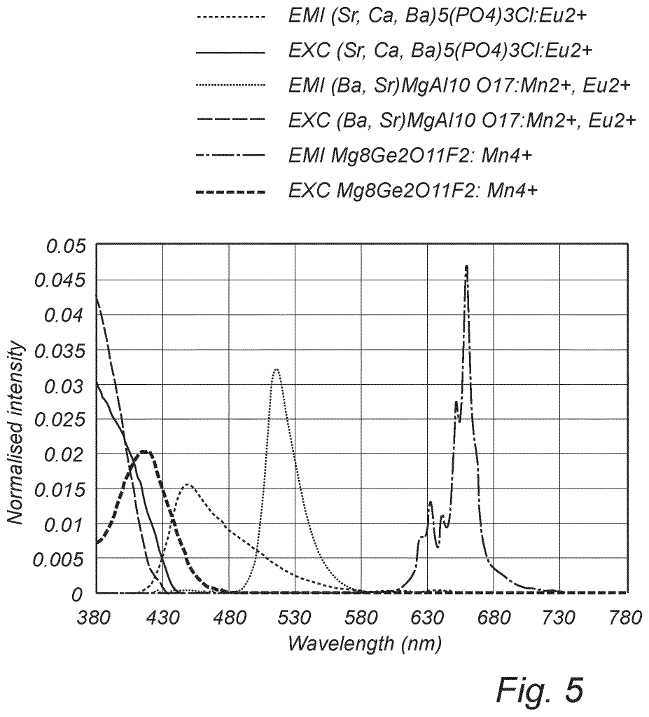

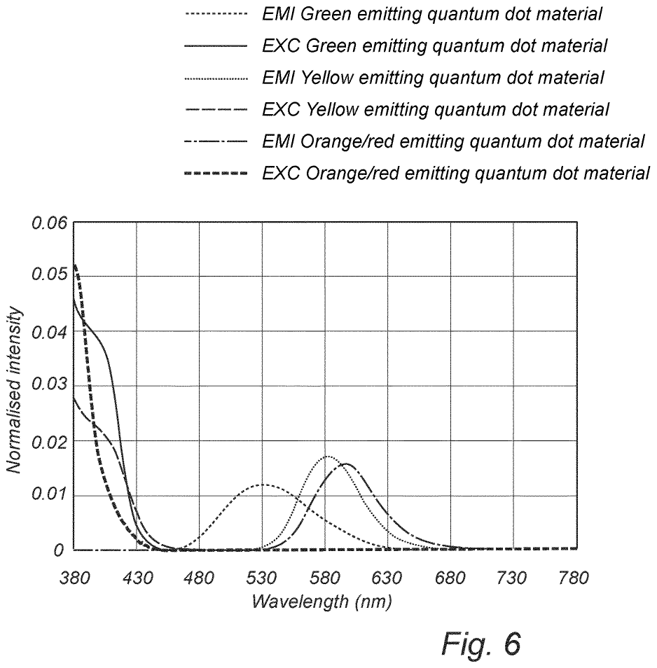

The graph of FIG. 5 illustrates the normalized intensity as a function of wavelength for each of the three phosphor materials listed above. The graph of FIG. 6 illustrates the normalized intensity as a function of wavelength for three different quantum dot materials, emitting green, yellow and orange/red light, respectively. In the graphs, the abbreviation “EXC” refers to the excitation spectrum of the material and the abbreviation “EMI” refers to the emission spectrum of the material. The graphs of FIGS. 5 and 6 show phosphor materials that emit in the yellow-red region and are not, or hardly, excited by (royal) blue light.

Turning now to FIG. 2, a top view of a light emitting device, LED, filament 100 according to another embodiment of the invention is shown. FIG. 3 shows a cross sectional side view of the LED filament 100. The LED filament 100 of FIG. 2 differs from the LED filament 1 of FIG. 1 described above in virtue of the following features.

The LED filament 100 comprises a first filament string 2a and a second filament string 2b. The phosphor structure 3 is arranged on the first filament string 2a and on the second filament string 2b. The phosphor structure 3 comprises two parts 3a and 3b. One of the parts 3a, 3b, in the embodiment shown the part 3a, comprises a phosphor adapted for generating cold white (CW) light. The other of the parts 3a, 3b, in the embodiment shown the part 3b, comprises phosphor adapted for generating warm white (WW) light. Thus, one of the first filament string 2a and the second filament string 2b, in the embodiment shown the first filament string 2a, comprises the phosphor adapted for generating cold white (CW) light, and the other of the first filament string 2a and the second filament string 2b, in the embodiment shown the second filament string 2b, comprises the phosphor adapted for generating warm white (WW) light.

The Phosphor adapted for generating WW light, here comprised by the second part 3b of the phosphor structure 3, may in this embodiment comprise a red phosphor arranged underneath a Phosphor adapted for generating CW light, where the Phosphor adapted for generating CW light of the same type as the Phosphor adapted for generating CW light comprised by the first part 3a of the phosphor structure 3.

Each of the first filament string 2a and the second filament string 2b may comprise first, second, third and fourth LEDs 4, 5, 6, 7 arranged in the same way as described above for the LED filament 1 shown in FIG. 1. It is furthermore feasible to arrange the first filament string 2a and the second filament string 2b (or the respective LEDs 4, 5, 6, 7 on the first filament string 2a and the second filament string 2b) in such a way with respect to each other that identical LEDs, for instance first LEDs 4, of each filament string are arranged offset with respect to each other in the longitudinal direction L of the filament strings 2a, 2b.

In an alternative, the plurality of first LEDs 4 adapted for, in operation, emitting first LED light may be arranged on the first filament string 2a, and the plurality of second LEDs 5 adapted for, in operation, emitting second LED light, the plurality of third LEDs 6 adapted for, in operation, emitting third LED light, and the plurality of fourth LEDs 7 adapted for, in operation, emitting fourth LED light may be arranged on the second filament 2b.

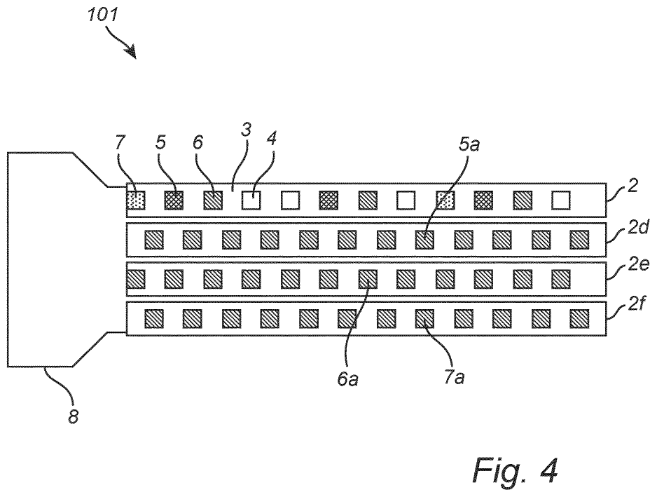

In either case it is also feasible to provide LED filaments 100 with more than two filament strings with LEDs arranged as described in any of the above variants. Turning now to FIG. 4, a top view of a light emitting device, LED, filament 101 according to yet another embodiment of the invention is shown. The LED filament 101 of FIG. 4 differs from those described above in relation to FIGS. 1-3 in virtue of the following features.

The LED filament 101 comprises a filament string 2 according to any of the above embodiments. In FIG. 4, a filament string 2 according to the embodiment shown in FIG. 1 is shown by way of example.

The LED filament 101 comprises one or more further filament strings, in the embodiment illustrated three further filament strings 2d, 2e and 2f. A further plurality of second LEDs 5a adapted for, in operation, emitting second LED light is arranged on the further filament string 2d. A further plurality of third LEDs 6a adapted for, in operation, emitting third LED light is arranged on the further filament strings 2e. A further plurality of fourth LEDs 7a adapted for, in operation, emitting fourth LED light is arranged on the further filament string 2f.

Thus, FIG. 4 illustrates an embodiment in which a LED filament 1, 101 according to any of the above embodiments described in relation to FIGS. 1-3 may be used together with blue, green and red LEDs 5, 6, 7 arranged on separate filaments or filament strings 2d, 2e, 2f.

It is noted that in the embodiment shown on FIG. 4 each further filament string 2d-2f comprises only one of further second, third and fourth LEDs 5a-7a. In other variants each further filament string 2d-2f may comprises two or more of further second, third and fourth LEDs 5a-7a, such as for instance RGB-groups. Combinations thereof are also feasible. In yet another variant, only first LEDs 4 may be arranged on the filament string 2.

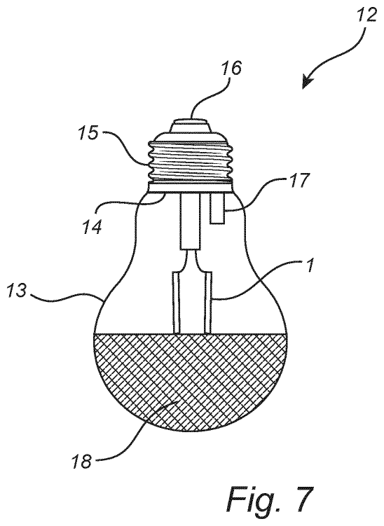

Finally, FIG. 7 shows an exemplary lamp 12 comprising a LED filament 1 according to any embodiment of the invention. In the embodiment shown, the LED filament 1 is a substantially straight LED filament. The LED filament 1 of such a lamp may in other embodiments be a LED filament with another shape, such as, but not limited to, spiral-shaped, helix-shaped, meandering, twisted, flat and combinations thereof.

The lamp 12 further comprises a driver or controller 17 configured for controlling the LED filament light source of the LED filament 1. The controller 17 is configured to power the plurality of LEDs 20 via the electrical circuitry 21 of the LED filament 1. The controller 17 may further be configured for controlling at least one of the CCT of the LED filament light source light and the CRI of the LED filament light source light. The controller 17 may also be configured for controlling other parameters related to the LED filament light source and the LED filament light source light.

The lamp 12 further comprises an envelope 13 at least partially enveloping the at least one LED filament 1. The lamp 12 further comprises a cap 14. As shown in FIG. 7, the controller 17 is arranged within the envelope 13. When comprising a cap 14, the controller 17 may also be arranged inside the cap 14 such that it is hidden from view. The lamp 12 further comprises threading 15 for connection to a socket and a terminal 16 for connection to a source of electrical energy.

The envelope 13 of the lamp 12 may further and optionally be provided with a coating 18, such as a reflective coating, covering at least a part of the envelope 13.

The person skilled in the art realizes that the present invention by no means is limited to the preferred embodiments described above. On the contrary, many modifications and variations are possible within the scope of the appended claims.

Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage.

1. A light emitting device, LED, filament configured to, in operation, emit LED filament light, the LED filament comprising:
a phosphor structure,
a plurality of first LEDs adapted for, in operation, emitting first LED light, the plurality of first LEDs and the phosphor structure being arranged in such a way with respect to each other that the phosphor structure, in operation, is receiving the first LED light,
a plurality of second LEDs adapted for, in operation, emitting second LED light, the second LED light being red light, the plurality of second LEDs and the phosphor structure being arranged in such a way with respect to each other that the phosphor structure, in operation, is receiving the second LED light,
a plurality of third LEDs adapted for, in operation, emitting third LED light, the third LED light being green light, the plurality of third LEDs and the phosphor structure being arranged in such a way with respect to each other that the phosphor structure, in operation, is receiving the third LED light,
a plurality of fourth LEDs adapted for, in operation, emitting fourth LED light, the fourth LED light being blue light, the plurality of fourth LEDs and the phosphor structure being arranged in such a way with respect to each other that the phosphor structure, in operation, is receiving the fourth LED light,
an electrical circuitry coupled to the first, second, third and fourth plurality of LEDs, and
an elongated carrier the plurality of first, second, third and fourth LEDs being arranged on a first major surface of the elongated carrier, wherein
the phosphor structure comprises at least one of a phosphor adapted for generating cold white light and a phosphor adapted for generating warm white light in combination with one or more of the second LED light, the third LED light and the fourth LED light, wherein
the phosphor structure is configured to convert less than 10% of the second LED light, third LED light and fourth LED light, and wherein
the first LED light comprises or is light with a peak wavelength in the range of 380-440 nm or 380-410 nm or 400-410 nm or of 405 nm, and the phosphor structure is configured to be excited by light having a wavelength corresponding to that of the first light.

2. The LED filament according to claim 1, wherein the plurality of first, second, third and fourth LEDs are arranged in sequences of a first LED followed by a group comprising a second LED, a third LED and a fourth LED.

3. The LED filament according to claim 1, wherein the LED filament comprises one single filament string.

4. The LED filament according to claim 1, wherein the LED filament comprises a first filament string and a second filament string, and wherein the phosphor structure is arranged on the first filament string and on the second filament string in such a way that one of the first filament string and the second filament string comprises the phosphor adapted for generating cold white light in combination with one or more of the second LED light, the third LED light and the fourth LED light, and that the other of the first filament string and the second filament string comprises the phosphor adapted for generating warm white light in combination with one or more of the second LED light, the third LED light and the fourth LED light.

5. The LED filament according to claim 4, wherein the phosphor adapted for generating WW light comprises a red phosphor arranged underneath a phosphor adapted for generating CW light of the same type as the phosphor adapted for generating CW light comprised by the one of the first filament string and the second filament string which comprises the phosphor adapted for generating CW light.

6. The LED filament according to claim 4, wherein each of the first filament string and the second filament string comprises a plurality of first LEDs adapted for, in operation, emitting first light, the plurality of first LEDs and the phosphor structure being arranged in such a way with respect to each other that the phosphor structure, in operation, is receiving the first light.

7. The LED filament according to claim 4, wherein each of the first filament string and the second filament string comprises a plurality of second LEDs adapted for, in operation, emitting second LED light, the second LED light being red light, the plurality of second LEDs and the phosphor structure being arranged in such a way with respect to each other that the phosphor structure, in operation, is receiving the second light, a plurality of third LEDs adapted for, in operation, emitting third LED light, the third LED light being green light, the plurality of third LEDs and the phosphor structure being arranged in such a way with respect to each other that the phosphor structure, in operation, is receiving the third light, and a plurality of fourth LEDs adapted for, in operation, emitting fourth LED light, the fourth LED light being blue light, the plurality of fourth LEDs and the phosphor structure being arranged in such a way with respect to each other that the phosphor structure, in operation, is receiving the fourth light.

8. The LED filament according to claim 1, wherein the LED filament comprises at least a first filament string and a second filament string, wherein
the plurality of first LEDs adapted for, in operation, emitting first LED light and the phosphor structure is arranged on the first filament string, and wherein
the plurality of second LEDs adapted for, in operation, emitting second LED light, the plurality of third LEDs adapted for, in operation, emitting third LED light, and the plurality of fourth LEDs adapted for, in operation, emitting fourth LED light is arranged on the second filament string

9. The LED filament according to claim 1, wherein the LED filament comprises one or more further filament strings, and wherein:
a further plurality of second LEDs adapted for, in operation, emitting second LED light is arranged on at least one of the one or more further filament strings,
a further plurality of third LEDs adapted for, in operation, emitting third LED light is arranged on least one of the one or more further filament strings, and
a further plurality of fourth LEDs adapted for, in operation, emitting fourth LED light is arranged on at least one of the one or more further filament strings.

10. The LED filament according to claim 1, wherein the phosphor structure is of a type which, when exposed to light, emits in any one or more of the yellow and red wavelength region and is not excited by light in any one or more of the green and blue wavelength region.

11. The LED filament according to claim 1, wherein the phosphor structure is of a type which is not excited by light with a wavelength in the blue region.

12. The LED filament according to claim 1, wherein the phosphor structure is of a type which is not excited by light in the wavelength region of 550 nm to 610 nm.

13. The LED filament according to claim 1, claims, wherein the phosphor structure comprises at least one phosphor chosen from the group comprising:
Violet pumped blue (VB) phosphors,
(Sr, Ca, Ba)5(PO4)3Cl:Eu2+,
Violet pumped green (VG) phosphors,
(Ba, Sr)MgAl10O17:Mn2+, Eu2+, and
Violet pumped red (VR) phosphors, Mg8Ge2O11F2:Mn4+.

14. The LED filament according to claim 1, wherein the phosphor structure comprises at least one phosphor chosen from the group comprising Quantum dots materials with violet absorption and emission in green, yellow or orange/red.

15. A luminaire or a lamp comprising a LED filament according to claim 1.
